(19) United States
(12) Patent Application Publication
(10) Pub. No.: US 2019/0090358 A1
(43) Pub. Date: Mar. 21, 2019

(54) COATED ELECTRICAL ASSEMBLY

(71) Applicant: Semblant Limited, London (GB)

(72) Inventors: Gianfranco Aresta, Stapleford (GB); Gareth Hennighan, Royston (GB); Andrew Simon Hall Brooks, Melbourn (GB); Shailendra Vikram Singh, Cambridge (GB)

(21) Appl. No.: 16/046,075

(22) Filed: Jul. 26, 2018

Related U.S. Application Data
(63) Continuation of application No. 15/266,624, filed on Sep. 15, 2016, now abandoned.
Application No. 15/266,624 is a continuation of application No. PCT/GB2016/051702, filed on Jun. 9, 2016.

(30) Foreign Application Priority Data
Jun. 10, 2015 (GB) 1510091.0

(51) Int. Cl. H05K 3/46; C23C 16/30; C23C 16/505; H05K 3/28; H05K 1/18

(52) U.S. Cl. CPC H05K 3/467; C23C 16/30; H05K 2201/10053; H05K 2201/10075; H05K 2201/10083; H05K 2201/10098; H05K 2201/10106; H05K 2201/10121; H05K 2201/10128; H05K 2201/10166; H05K 2201/10181; C23C 16/505; H05K 2203/1338; H05K 2203/1322; H05K 2203/121; H05K 2201/09872; H05K 3/285; H05K 2203/095; H05K 2201/10174; H05K 1/181; H05K 2201/0104; H05K 2201/0162; H05K 2201/10015; H05K 2201/10022; H05K 2201/1003; H05K 2201/10037

(57) ABSTRACT

An electrical assembly which has a multi-layer conformal coating on at least one surface of the electrical assembly, wherein each layer of the multi-layer coating is obtainable by plasma deposition of a precursor mixture comprising (a) one or more organosilicon compounds, (b) optionally O₂, N₂O, NO₂, H₂, NH₃, N₂, SiF₄ and/or hexafluoropropylene (HFP), and (c) optionally He, Ar and/or Kr. The chemistry of the resulting plasma-deposited material chemistry can be described by the general formula: SiOₓH_{y}C_{z}FₐN_{b}. The properties of the conformal coating are tailored by tuning the values of x, y, z, a and b.

### CROSS-REFERENCES TO RELATED APPLICATIONS

This application is a Continuation of U.S. application Ser. No. 15/266,624 filed on Sep. 15, 2016, which is a Continuation of PCT Application No. PCT/GB2016/051702, filed on Jun. 9, 2016, the disclosure of each application is incorporated herein by reference in their entirety.

### FIELD OF THE INVENTION

The present invention relates to a coated electrical assembly and to methods of preparing a coated electrical assembly.

### BACKGROUND TO THE INVENTION

Conformal coatings have been used for many years in the electronics industry to protect electrical assemblies from environmental exposure during operation. A conformal coating is a thin and flexible layer of protective lacquer that conforms to the contours of an electrical assembly, such as a printed circuit board, and its components.

There are 5 main classes of conformal coatings, according to the IPC definitions: AR (acrylic), ER (epoxy), SR (silicones), UR (urethanes) and XY (paraxylylene). Of these 5 types, paraxylylene (or parylene) is generally accepted to offer the best chemical, electrical and physical protection. This deposition process is time consuming and expensive, and the starting material is expensive.

Plasma processed polymers/coatings have emerged as promising alternatives to conventional conformal coatings. Conformal coatings deposited by plasma-polymerization techniques have been described in, for example, WO 2011/104500 and WO 2013/132250.

Despite these developments, there remains a need for further conformal coatings that offer at least similar levels of chemical, electrical and physical protection as commercially available coatings, but that can be manufactured more easily and cheaply. There also remains a need for coatings that achieve increased levels of moisture protection as compared to commercially available coatings, and thus achieve high levels of waterproof protection.

### SUMMARY OF THE INVENTION

The present inventors have surprisingly found that organosilicon compounds can be deposited by plasma deposition to provide multi-layer conformal coatings that provide high levels of chemical, electrical and physical protection. The excellent moisture-barrier properties of such coatings are particularly desirable, and potentially could result in coated electrical assemblies with a much higher level of waterproofing than is currently available. In addition, the inventors have tuned the plasma chemistry and engineered the material structure so that such coatings are hard and have excellent scratch resistance.

The present invention thus relates to an electrical assembly which has a multi-layer conformal coating on at least one surface of the electrical assembly, wherein each layer of the multi-layer coating is obtainable by plasma deposition of a precursor mixture comprising (a) one or more organosilicon compounds, (b) optionally O₂, N₂O, NO₂, H₂, NH₃, N₂, SiF₄ and/or hexafluoropropylene (HFP), and (c) optionally He, Ar and/or Kr.

The invention also relates to an electrical component which has a multi-layer conformal coating on at least one surface of electrical component, wherein each layer of the multi-layer coating is obtainable by plasma deposition of a precursor mixture comprising (a) one or more organosilicon compounds, (b) optionally O₂, N₂O, NO₂, H₂, NH₃, N₂, SiF₄ and/or hexafluoropropylene (HFP), and (c) optionally He, Ar and/or Kr.

### BRIEF DESCRIPTION OF THE FIGURES

FIG. 1 shows an example of an electrical assembly of the invention which has a multi-layer conformal coating.

FIGS. 2 to 4 show cross sections through the multi-layer conformal coating in FIG. 1, and depict the structures of preferred coatings.

FIG. 5 shows the Fourier transform infrared (FTIR) spectrum for the coating prepared in Example 1.

FIG. 6 shows the FTIR spectrum for the coating prepared in Example 2.

FIG. 7 shows the results from Example 4, in which combs were coated with various multi-layer conformal coatings and then tested for electrical resistance when coated with water.

### DETAILED DESCRIPTION OF THE INVENTION

The multi-layer conformal coatings of the invention comprise layers which are obtainable by plasma deposition of organosilicon compounds. The organosilicon compound(s) can be deposited in the presence or absence of reactive gases and/or non-reactive gases. The resulting layers deposited have general formula SiOₓH_{y}C_{z}FₐN_{b}, wherein the values of x, y, z, a and b depend upon (a) the specific organosilicon compound(s) used, (b) whether or not a reactive gas is present and the identify of that reactive gas, and (c) whether or not a non-reactive gas is present, and the identify of that non-reactive gas. For example, if no fluorine or nitrogen is present in the organosilicon compound(s) and a reactive gas containing fluorine or nitrogen is not used, then the values of a and b will be 0. As will be discussed in further detail below, the values of x, y, z, a and b can be tuned by selecting appropriate organosilicon compound(s) and/or reactive gases, and the properties of each layer and the overall coating controlled accordingly.

For the avoidance of doubt, it will be appreciated that each layer of the multilayer coating may have organic or inorganic character, depending upon the exact precursor mixture, despite the organic nature of the precursor mixtures used to form those layers. In an organic layer of general formula SiOₓH_{y}C_{z}FₐN_{b}, the values of y and z will be greater than zero, whereas in an inorganic layer of general formula SiOₓH_{y}C_{z}FₐN_{b} the values of y and z will tend towards zero. The organic nature of a layer can easily be determined by a skilled person using routine analytical techniques, such as by detecting the presence of carbon-hydrogen and/or carbon-carbon bonds using Fourier transform infrared spectroscopy. Similarly, the inorganic nature of a layer can easily be determined by a skilled person using routine analytical techniques, such as by detecting the absence of carbon-hydrogen and/or carbon-carbon bonds using Fourier transform infrared spectroscopy.

### Plasma Deposition Process

The layers present in the multi-layer conformal coatings of the invention are obtainable by plasma deposition, typically plasma enhanced chemical vapour deposition (PECVD) or plasma enhanced physical vapour deposition (PEPVD), preferably PECVD, of a precursor mixture. The plasma deposition process is typically carried out at a reduced pressure, typically 0.001 to 10 mbar, preferably 0.01 to 1 mbar, for example about 0.7 mbar. The deposition reactions occur in situ on the surface of the electrical assembly, or on the surface of layers that have already been deposited.

Plasma deposition is typically carried out in a reactor that generates plasma which comprises ionized and neutral feed gases/precursors, ions, electrons, atoms, radicals and/or other plasma generated neutral species. A reactor typically comprises a chamber, a vacuum system, and one or more energy sources, although any suitable type of reactor configured to generate plasma may be used. The energy source may include any suitable device configured to convert one or more gases to a plasma. Preferably the energy source comprises a heater, radio frequency (RF) generator, and/or microwave generator.

Plasma deposition results in a unique class of materials which cannot be prepared using other techniques. Plasma deposited materials have a highly disordered structure and are generally highly cross-linked, contain random branching and retain some reactive sites. These chemical and physical distinctions are well known and are described, for example in Plasma Polymer Films, Hynek Biederman, Imperial College Press 2004 and Principles of Plasma Discharges and Materials Processing, 2^{nd} Edition, Michael A. Lieberman, Alan J. Lichtenberg, Wiley 2005.

Typically, the electrical assembly is placed in the chamber of a reactor and a vacuum system is used to pump the chamber down to pressures in the range of 10⁻³ to 10 mbar. One or more gases is typically then injected (at controlled flow rate) into the chamber and an energy source generates a stable gas plasma. One or more precursor compounds is typically then be introduced, as gases and/or vapours, into the plasma phase in the chamber. Alternatively, the precursor compound may be introduced first, with the stable gas plasma generated second. When introduced into the plasma phase, the precursor compounds are typically decomposed (and/or ionized) to generate a range of active species (i.e. radicals) in the plasma that is deposited onto and forms a layer on the exposed surface of electrical assembly.

The exact nature and composition of the material deposited typically depends on one or more of the following conditions (i) the plasma gas selected; (ii) the particular precursor compound(s) used; (iii) the amount of precursor compound(s) [which may be determined by the combination of the pressure of precursor compound(s), the flow rate and the manner of gas injection]; (iv) the ratio of precursor compound(s); (v) the sequence of precursor compound(s); (vi) the plasma pressure; (vii) the plasma drive frequency; (viii) the power pulse and the pulse width timing; (ix) the coating time; (x) the plasma power (including the peak and/or average plasma power); (xi) the chamber electrode arrangement; and/or (xii) the preparation of the incoming assembly.

Typically the plasma drive frequency is 1 kHz to 4 GHz. Typically the plasma power density is 0.001 to 50 W/cm², preferably 0.01 W/cm² to 0.02 W/cm², for example about 0.0175 W/cm². Typically the mass flow rate is 5 to 1000 sccm, preferably 5 to 20 sccm, for example about 10 sccm. Typically the operating pressure is 0.001 to 10 mbar, preferably 0.01 to 1 mbar, for example about 0.7 mbar. Typically the coating time is 10 seconds to >60 minutes, for example 10 seconds to 60 minutes.

Plasma processing can be easily scaled up, by using a larger plasma chamber. However, as a skilled person will appreciate, the preferred conditions will be dependent on the size and geometry of the plasma chamber. Thus, depending on the specific plasma chamber that is being used, it may be beneficial for the skilled person to modify the operating conditions.

### Precursor Compounds

The multi-layer conformal coatings of the invention comprise layers which are obtainable by plasma deposition of a precursor mixture. The precursor mixture comprises one or more organosilicon compounds, and optionally further comprises a reactive gas (such as O₂) and/or a non-reactive gas (such as Ar). The resulting layers deposited have general formula SiOₓH_{y}C_{z}FₐN_{b}, wherein the values of x, y, z, a and b depend upon (i) the specific organosilicon compound(s) used, and (ii) whether or not a reactive gas is present and the identify of that reactive gas.

Typically the precursor mixture consists, or consists essentially, of the one or more organosilicon compounds, the optional reactive gas(es) and the optional non-reactive gas(es). As used herein, the term “consists essentially of” refers to a precursor mixture comprising the components of which it consists essentially as well as other components, provided that the other components do not materially affect the essential characteristics of the resulting layer formed from the precursor mixture. Typically, a precursor mixture consisting essentially of certain components will contain greater than or equal to 95 wt % of those components, preferably greater than or equal to 99 wt % of those components.

When the one or more organosilicon compounds are plasma deposited in the absence of an excess of oxygen and nitrogen-containing reactive gas (such as NH₃, O₂, N₂O or NO₂), the resulting layer will be organic in nature and will be of general formula SiOₓH_{y}C_{z}FₐN_{b}. The values of y and z will be greater than 0. The values of x, a and b will be greater than 0 if O, F or N is present in the precursor mixture, either as part of the organosilicon compound(s) or as a reactive gas.

When the one or more organosilicon compounds are plasma deposited in the presence of oxygen-containing reactive gas (such as O₂ or N₂O or NO₂), the hydrocarbon moieties in the organosilicon precursor react with the oxygen-containing reactive gas to form CO₂ and H₂O. This will increase the inorganic nature of the resulting layer. If sufficient oxygen-containing reactive gas is present, all of the hydrocarbon moieties maybe removed, such that resulting layer is substantially inorganic/ceramic in nature (in which in the general formula SiOₓH_{y}C_{z}FₐN_{b}, y, z, a and b will have negligible values tending to zero). The hydrogen content can be reduced further by increasing RF power density and decreasing plasma pressure, thus enhancing the oxidation process and leading to a dense inorganic layer (in which in the general formula SiOₓH_{y}C_{z}FₐN_{b}, x is as high as 2 with y, z, a and b will have negligible values tending to zero).

Typically, the precursor mixture comprises one organosilicon compound, but it may be desirable under some circumstances to use two or more different organosilicon compounds, for example two, three or four different organosilicon compounds.

Typically, the organosilicon compound is an organosiloxane, an organosilane, a nitrogen-containing organosilicon compound such as a silazane or an aminosilane, or a halogen-containing organosilicon compound such as a halogen-containing organosilane. The organosilicon compound may be linear or cyclic.

The organosilicon compound may be a compound of formula (I):

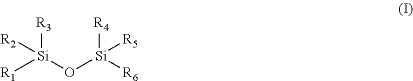

wherein each of R₁ to R₆ independently represents a C₁-C₆ alkyl group, a C₂-C₆ alkenyl group or hydrogen, provided that at least one of R₁ to R₆ does not represent hydrogen. Preferably, each of R₁ to R₆ independently represents a C₁-C₃ alkyl group, a C₂-C₄ alkenyl group or hydrogen, for example methyl, ethyl, vinyl, allyl or hydrogen, provided that at least one of R₁ to R₆ does not represent hydrogen. Preferably at least two or three, for example four, five or six, of R₁ to R₆ do not represent hydrogen. Preferred examples include hexamethyldisiloxane (HMDSO), tetramethyldisiloxane (TMD SO), 1,3-divinyltetramethyldisiloxane (DVTMDSO) and hexavinyldisiloxane (HVDSO). Hexamethyldisiloxane (HMD SO) and tetramethyldisiloxane (TMDSO) are particularly preferred, with hexamethyldisiloxane (HMDSO) most preferred.

Alternatively, the organosilicon compound may be a compound of formula (II):

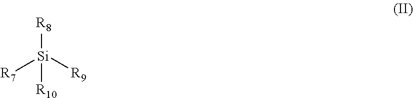

wherein each of R₇ to R₁₀ independently represents a C₁-C₆ alkyl group, a C₁-C₆ alkoxy group, a C₂-C₆ alkenyl group, hydrogen, or a —(CH₂)₁₋₄NR′R″ group in which R′ and R″ independently represent a C₁-C₆ alkyl group, provided that at least one of R₇ to R₁₀ does not represent hydrogen. Preferably each of R₇ to R₁₀ independently represents a C₁-C₃ alkyl group, C₁-C₃ alkoxy group, a C₂-C₄ alkenyl group, hydrogen or —(CH₂)₂₋₃NR′R″ group in which R′ and R″ independently represent a methyl or ethyl group, for example methyl, ethyl, isopropyl, methoxy, ethoxy, vinyl, allyl, hydrogen or —CH₂CH₂CH₂N(CH₂CH₃)₂, provided that at least one of R₇ to R₁₀ does not represent hydrogen. Preferably at least two, for example three or four, of R₇ to R₁₀ do not represent hydrogen. Preferred examples include allyltrimethylsilane, allyltrimethoxysilane (ATMOS), tetraethylorthosilicate (TEOS), 3-(diethylamino)propyl-trimethoxysilane, trimethylsilane (TMS) and triisopropylsilane (TiPS).

Alternatively, the organosilicon compound may be a cyclic compound of formula (III):

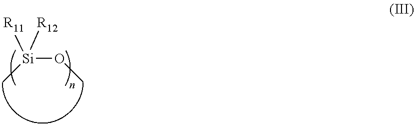

wherein n represents 3 or 4, and each of R₁₁ and R₁₂ each independently represents a C₁-C₆ alkyl group, a C₂-C₆ alkenyl group or hydrogen, provided that at least one of R₁₁ and R₁₂ does not represent hydrogen. Preferably, each of R₁₁ and R₁₂ independently represents a C₁-C₃ alkyl group, a C₂-C₄ alkenyl group or hydrogen, for example methyl, ethyl, vinyl, allyl or hydrogen, provided that at least one of R₁₁ and R₁₂ does not represent hydrogen. Preferred examples include trivinyl-trimethyl-cyclotrisiloxane (V₃D₃), tetravinyl-tetramethyl-cyclotetrasiloxane (V₄D₄), tetramethylcyclotetrasiloxane (TMCS) and octamethylcyclotetrasiloxane (OMCTS).

Alternatively, the organosilicon compound may be a compound of formula (IV):

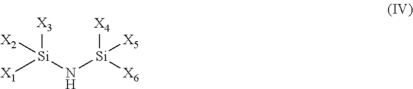

wherein each of X₁ to X₆ independently represents a C₁-C₆ alkyl group, a C₂-C₆ alkenyl group or hydrogen, provided that at least one of X₁ to X₆ does not represent hydrogen. Preferably each of X₁ to X₆ independently represents a C₁-C₃ alkyl group, a C₂-C₄ alkenyl group or hydrogen, for example methyl, ethyl, vinyl, allyl or hydrogen, provided that at least one of X₁ to X₆ does not represent hydrogen. Preferably at least two or three, for example four, five or six, of X₁ to X₆ do not represent hydrogen. A preferred example is hexamethyldisilazane (HMDSN).

Alternatively, the organosilicon compound may be a cyclic compound of formula (V):

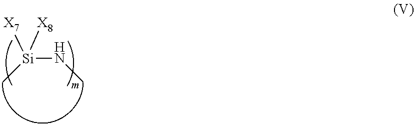

wherein m represents 3 or 4, and each of X₇ and X₈ independently represents a C₁-C₆ alkyl group, a C₂-C₆ alkenyl group or hydrogen, provided that at least one of X₇ and X₈ does not represent hydrogen. Preferably, each of X₇ and X₈ independently represents a C₁-C₃ alkyl group, a C₂-C₄ alkenyl group or hydrogen, for example methyl, ethyl, vinyl, allyl or hydrogen, provided that at least one of X₇ and X₈ does not represent hydrogen. A preferred example is 2,4,6-trimethyl-2,4,6-trivinylcyclotrisilazane.

Alternatively, the organosilicon compound may be a compound of formula (VI):

Hₐ(X⁹)_{b}Si(N(X¹⁰)₂)_{4-a-b} (VI)

wherein X⁹ and X¹⁰ independently represent C₁-C₆ alkyl groups, a represents 0, 1 or 2, b represents 1, 2 or 3, and the sum of a and b is 1, 2 or 3. Typically, X⁹ and X¹⁰ represent a C₁-C₃ alkyl group, for example methyl or ethyl. Preferred examples are dimethylamino-trimethylsilane (DMATMS), bis(dimethylamino)dimethylsilane (BDMADMS) and tris(dimethylamino)methylsilane (TDMAMS).

Alternatively, the organosilicon compound may be a compound of formula (VII):

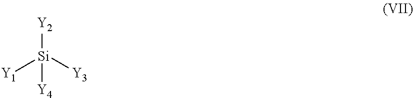

wherein each of Y₁ to Y₄ independently represents a C₁-C₈ haloalkyl group, a C₁-C₆ alkyl group, C₁-C₆ alkoxy group, or a C₂-C₆ alkenyl group or hydrogen, provided that at least one of Y₁ to Y₄ represents a C₁-C₈ haloalkyl group. Preferably, each of Y₁ to Y₄ independently represents a C₁-C₃ alkyl group, C₁-C₃ alkoxy group, a C₂-C₄ alkenyl group or a C₁-C₈ haloalkyl group, for example methyl, ethyl, methoxy, ethoxy, vinyl, allyl, trifluoromethyl or 1H,1H,2H,2H-perfluorooctyl, provided that at least one of Y₁ to Y₄ represents a haloalkyl group. Preferred examples are trimethyl(trifluoromethyl)silane and 1H,1H,2H,2H-perfluorooctyltriethoxysilane.

Preferably the organosilicon compound is hexamethyldisiloxane (HMDSO), tetramethyldisiloxane (TMDSO), 1,3-divinyltetramethyldisiloxane (DVTMDSO), hexavinyldisiloxane (HVDSO allyltrimethylsilane, allyltrimethoxysilane (ATMOS), tetraethylorthosilicate (TEOS), 3-(diethylamino)propyl-trimethoxysilane, trimethylsilane (TMS), triisopropylsilane (TiPS), trivinyl-trimethyl-cyclotrisiloxane (V₃D₃), tetravinyl-tetramethyl-cyclotetrasiloxane (V₄D₄), tetramethylcyclotetrasiloxane (TMCS), octamethylcyclotetrasiloxane (OMCTS), hexamethyldisilazane (HMDSN), 2,4,6-trimethyl-2,4,6-trivinylcyclotrisilazane, dimethylamino-trimethylsilane (DMATMS), bis(dimethylamino)dimethylsilane, (BDMADMS), tris(dimethylamino)methylsilane (TDMAMS), trimethyl(trifluoromethyl)silane or 1H,1H,2H,2H-perfluorooctyltriethoxysilane. Hexamethyldisiloxane (HIVIDSO) and tetramethyldisiloxane (TMDSO) are particularly preferred, with hexamethyldisiloxane (HMDSO) most preferred.

As used herein, the term C₁-C₆ alkyl embraces a linear or branched hydrocarbon groups having 1 to 6, preferably 1 to 3 carbon atoms. Examples include methyl, ethyl, n-propyl and i-propyl, butyl, pentyl and hexyl.

As used herein, the term C₂-C₆ alkenyl embraces a linear or branched hydrocarbon groups having 2 or 6 carbon atoms, preferably 2 to 4 carbon atoms, and a carbon-carbon double bond. Preferred examples include vinyl and allyl.

As used herein, a halogen is typically chlorine, fluorine, bromine or iodine and is preferably chlorine, bromine or fluorine, most preferably fluorine.

As used herein, the term C₁-C₆ haloalkyl embraces a said C₁-C₆ alkyl substituted by one or more said halogen atoms. Typically, it is substituted by 1, 2 or 3 said halogen atoms. Particularly preferred haloalkyl groups are —CF₃ and —CCl₃.

As used herein, the term C₁-C₆ alkoxy group is a said alkyl group which is attached to an oxygen atom. Preferred examples include methoxy, ethoxy, propoxy, isopropoxy, butoxy, isobutoxy, tert-butoxy, pentoxy and hexoxy.

The precursor mixture optionally further comprises a reactive gas. The reactive gas is selected from O₂, N₂O, NO₂, H₂, NH₃, N₂, SiF₄ and/or hexafluoropropylene (HFP). These reactive gases are generally involved chemically in the plasma deposition mechanism, and so can be considered to be co-precursors.

O₂, N₂O and NO₂ are oxygen-containing co-precursors, and are typically added in order to increase the inorganic character of the resulting layer deposited. This process is discussed above. N₂O and NO₂ are also nitrogen-containing co-precursors, and are typically added in order to increase additionally the nitrogen content of the resulting layer deposited (and consequently the value of b in the general formula SiOₓH_{y}C_{z}FₐN_{b} is increased).

H₂ is a reducing co-precursor, and is typically added in order to reduce the oxygen content (and consequently the value of x in the general formula SiOₓH_{y}C_{z}FₐN_{b}) of the resulting layer deposited. Under such reducing conditions, the carbon and hydrogen are also generally removed from the resulting layer deposited (and consequently the values of y and z in the general formula SiOₓH_{y}C_{z}FₐN_{b} are also reduced). Addition of H₂ as a co-precursor increases the level of cross-linking in the resulting layer deposited.

N₂ is a nitrogen-containing co-precursor, and is typically added in order to increase the nitrogen content of the resulting layer deposited (and consequently the value of b in the general formula SiOₓH_{y}C_{z}FₐN_{b} is increased).

NH₃ is also a nitrogen-containing co-precursor, and so is typically added in order to increase the nitrogen content of the resulting layer deposited (and consequently the value of b in the general formula SiOₓH_{y}C_{z}FₐN_{b} is increased). However, NH₃ additionally has reducing properties. As with the addition of H₂, this means that when NH₃ is used as a co-precursor, oxygen, carbon and hydrogen are generally removed from the resulting layer deposited (and consequently the values of x, y and z in the general formula SiOₓH_{y}C_{z}FₐN_{b} are reduced). Addition of NH₃ as a co-precursor increases the level of cross-linking in the resulting layer deposited. The resulting layer tends towards a silicon nitride structure.

SiF₄ and hexafluoropropylene (HFP) are fluorine-containing co-precursors, and typically added in order to increase the fluorine content of the resulting layer deposited (and consequently the value of a in the general formula SiOₓH_{y}C_{z}FₐN_{b} is increased).

A skilled person can easily adjust the ratio of reactive gas to organosilicon compound(s) at any applied power density, in order to achieve the desired modification of the resulting layer deposited.

The precursor mixture also optionally further comprises a non-reactive gas. The non-reactive gas is He, Ar or Kr. The non-reactive gas is not involved chemically in the plasma deposition mechanism, but does generally influence the physical properties of the resulting material. For example, addition of He, Ar or Kr will generally increase the density of the resulting layer, and thus its hardness. Addition of He, Ar or Kr also increases cross-linking of the resulting deposited material.

### Structure and Properties of the Multi-Layer Conformal Coating

The multi-layer conformal coating of the invention comprises at least two layers. The first, or lowest layer, in the multi-layer coating is in contact with the surface of the electrical assembly. The final, or uppermost layer, in the multi-layer coating is in contact with the environment. When the multi-layer conformal coating comprises more than two layers, then those additional layers will be located between the first/lowest and final/uppermost layers.

Typically, the multi-layer coating comprises from two to ten layers. Thus, the multilayer coating may have two, three, four, five, six, seven, eight, nine or ten layers. Preferably, the multilayer coating has from two to eight layers, for example from two to six layers, or from three to seven layers, or from four to eight layers.

The boundary between each layer may be discrete or graded. In a multi-layer coating that has more than two layers, each boundary between layers may be either discrete or graded. Thus, all of the boundaries may be discrete, or all of the boundaries may be graded, or there may be both discrete and graded boundaries with the multi-layer coating.

A graded boundary between two layers can be achieved by switching gradually over time during the plasma deposition process from the precursor mixture required to form the first of the two layers to the precursor mixture required to form the second of the two layers. The thickness of the graded region between the two layers can be adjusted by altering the time period over which the switch from the first precursor mixture to the second precursor mixture occurs. Under some circumstances graded boundaries can be advantageous, as the adhesion between layers is generally increased by a graded boundary.

A discrete boundary between two layers can be achieved by switching immediately during the plasma deposition process from the precursor mixture required to form the first of the two layers to the precursor mixture required to form the second of the two layers.

Different layers are deposited by varying the precursor mixture and/or the plasma deposition conditions in order to obtain layers which have the desired properties. The properties of each individual layer are selected such that the resulting multi-layer coating has the desired properties.

For the avoidance of doubt, all layers of the multi-layer coating of the invention are obtainable by plasma deposition of precursor mixtures as herein defined which contain one or more organosilicon compounds. Thus, the multi-layer coatings of the invention do not contain other layers which are not obtainable from precursor mixtures as herein defined, such as metallic or metal oxide layers.

### Properties of First/Lowest Layer in Particular

It is generally desirable for the multi-layer conformal coating to show good adhesion, both to the surface of the electrical assembly and between layers within the multi-layer conformal coating. This is desirable so that the multi-layer conformal coating is robust during use. Adhesion can be tested using tests known to those skilled in the art, such as a Scotch tape test or a scratch adhesion test.

It is preferable, therefore, that the first/lowest layer of the multi-layer conformal coating, which is in contact with the surface of the electrical assembly, is formed from a precursor mixture that results in a layer that adheres well to the surface of the electrical assembly. The exact precursor mixture that is required will depend upon the specific surface of the electrical assembly, and a skilled person will be able to adjust the precursor mixture accordingly. However, layers which are organic in character typically adhere best to the surface of the electrical assembly. Layers which contain no, or substantially no, fluorine also typically adhere best to the surface of the electrical assembly.

Typically, therefore, the first/lowest layer of the multi-layer conformal coating is organic. A layer with organic character can be achieved by using a precursor mixture that contains no, or substantially no, oxygen-containing reactive gas (i.e. no, or substantially no, or O₂, N₂O or NO₂). It is thus preferable that the first/lowest layer of the multi-layer conformal coating is deposited using a precursor mixture that contains no, or substantially no, O₂, N₂O or NO₂.

As used herein, the reference to a precursor mixture containing “substantially no” specified component(s) refers to a precursor mixture that may contain trace amounts of the specified component(s), provided that the specified component(s) do not materially affect the essential characteristics of the resulting layer formed from the precursor mixture. Typically, therefore a precursor mixture that contains substantially no specified component(s) contains less than 5 wt % of the specified component(s), preferably less than 1 wt % of the specified component(s), most preferably less than 0.1 wt % of the specified component(s).

A layer which contains no, or substantially no, fluorine can be achieved by using a precursor mixture that contains no, or substantially no, fluorine-containing organosilicon compound and no, or substantially no, fluorine-containing reactive gas (ie. no, or substantially no, SiF₄ or HFP). It is thus preferable that the first/lowest layer of the multi-layer conformal coating is deposited using a precursor mixture that contains no, or substantially no, fluorine-containing organosilicon compound, SiF₄ or HFP.

Accordingly, it is particularly preferred that the first/lowest layer of the multi-layer conformal coating is deposited using a precursor mixture that contains no, or substantially no, O₂, N₂O, NO₂, fluorine-containing organosilicon compound, SiF₄ or HFP. The resulting coating will be organic in character and contain no fluorine, and so will adhere well to the surface of the electrical assembly.

It is also generally desirable for the first/lowest layer of the multi-layer conformal coating to be capable of absorbing any residual moisture present on the substrate of the electrical assembly prior to deposition of the coating. The first/lowest layer will then generally retain the residual moisture within the coating, and thereby reduce the nucleation of corrosion and erosion sites on the substrate.

### Properties of the Final/Uppermost Layer

It is generally desirable for the final/uppermost layer of the multi-layer coating, that is to say the layer that is exposed to the environment, to be hydrophobic. Hydrophobicity can be determined by measuring the water contact angle (WCA) using standard techniques. Typically, the WCA of the final/uppermost layer of the multi-layer coating is >90°, preferably from 95° to 115°, more preferably from 100° to 110°.

The hydrophobicity of a layer can be modified by adjusting the precursor mixture. For example, a layer which has organic character will generally be hydrophobic. Typically, therefore, the final/uppermost layer of the multi-layer conformal coating is organic. A layer with organic character can be achieved, for example, by using a precursor mixture that contains no, or substantially no, oxygen-containing reactive gas (i.e. no, or substantially no, or O₂, N₂O or NO₂). As discussed above, if an oxygen-containing gas is present in the precursor mixture, the organic character and thus hydrophobicity of the resulting layer will be reduced. It is thus preferable that the final/uppermost layer of the multi-layer conformal coating is deposited using a precursor mixture that contains no, or substantially no, O₂, N₂O or NO₂.

The hydrophobicity of a layer can also be increased by using a halogen-containing organosilicon compound, such as the compounds of formula VII defined above. With such a precursor, the resulting layer will contain halogen atoms and will generally be hydrophobic. Halogen atoms can also be introduced by including SiF₄ or HFP as a reactive gas in the precursor mixture, which will result in the inclusion of fluorine in the resulting layer. It is thus preferable that the final/uppermost layer of the multi-layer conformal coating is deposited using a precursor mixture that comprises a halogen-containing organosilicon compound, SiF₄ and/or HFP.

It is also generally desirable for the final/uppermost layer of the multi-layer conformal coating to have a hardness of at least 4 GPa, preferably at least 6 GPa, more preferably at least 7 GPa. The hardness is typically no greater than 11 GPa. Hardness can be measured by nanohardness tester techniques known to those skilled in the art. The hardness of a layer can be modified by adjusting the precursor mixture, for example to include a non-reactive gas such as He, Ar and/or Kr. This results in a layer which is denser and thus harder. It is thus preferably that the final/uppermost layer of the multi-layer conformal coating is deposited using a precursor mixture that comprises He, Ar and/or Kr.

It is also possible to adjust the hardness by modifying the plasma deposition conditions. Thus, reducing the pressure at which deposition occurs generally results in a layer which is denser and thus harder. Increasing the RF power generally results in a layer which is denser and thus harder. These conditions and/or the precursor mixture can be readily adjusted to achieve a hardness of at least 6 GPa.

It is also generally desirable for the final/uppermost layer of the multi-layer conformal coating to be oleophobic. Generally, a layer that is hydrophobic will also be oloephobic. This is particularly the case for fluorine-containing coatings. Thus, if the water contact angle (WCA) of the final/uppermost layer of the multi-layer coating is greater than 100°, then the coating will be oleophobic. A WCA of greater than 105° is preferred for increased oleophobic properties.

In view of the above, it is particularly preferred that final/uppermost layer of the multi-layer conformal coating has (a) a WCA of from 90° to 120°, preferably from 95° to 115°, more preferably from 100° to 110°, and (b) a hardness of at least 6 GPa.

Overall, it is particularly preferred that the final/uppermost layer of the multi-layer conformal coating is deposited using a precursor mixture that (a) contains no, or substantially no, O₂, N₂O or NO₂, (b) comprises a halogen-containing organosilicon compound, SiF₄ and/or HFP, and (c) comprises He, Ar and/or Kr.

Although it is generally preferred that the final/uppermost layer of the multi-layer conformal coating is hydrophobic, it can also be desirable for the final/uppermost layer to have both hydrophobic and hydrophilic regions. These hydrophobic and hydrophilic regions can be deposited such that channels are formed on the final/uppermost layer that guide moisture away from, for example, moisture-sensitive components.

Typically, the final/uppermost layer of the multi-layer conformal coating is not inorganic, since the properties of such coatings are generally less favourable than coatings in which the final/uppermost layer is organic. When the multilayer coating has two or three layers, it is particularly preferred that the final/uppermost layer is not inorganic (ie. the final/uppermost layer is organic) . However, when the multilayer coating contains four or more layers, the differences in properties between coatings with an inorganic final/uppermost layer and coatings with an organic final/uppermost layer are generally less significant, and indeed it can be desirable to have an final/uppermost layer that is not organic under those circumstances to provide increased hardness.

### Moisture Barrier Properties

It is desirable for the multi-layer conformal coating to act as a moisture barrier, so that moisture, typically in the form or water vapour, cannot breach the multi-layer conformal coating and damage the underlying electrical assembly. The moisture barrier properties of the multi-layer conformal coating can be assessed by measuring the water vapour transmission rate (WVTR) using standard techniques, such as a MOCON test. Typically, the WVTR of the multi-layer conformal coating is from 10 g/m²/day down to 0.001 g/m²/day.

Typically, the moisture barrier properties of the multi-layer conformal coating may be enhanced by inclusion of at least one layer which has a WVTR of from 0.5 g/m²/day down to 0.1 g/m²/day. This moisture barrier layer is typically not the first/lowest or final/uppermost layer of the multi-layer conformal coating. Several moisture barrier layers may be present in a multi-layer coating, each of which may have the same or different composition.

Generally, layers which are substantially inorganic in character and contain very little carbon are the most effective moisture barriers. Such layers can be obtained by, for example, plasma deposition of a precursor mixture that comprises an organosilicon compound and an oxygen-containing reactive gas (ie. O₂, N₂O or NO₂). Addition of a non-reactive gases such as He, Ar or Kr, use of a high RF power density and/or reducing the plasma pressure will also assist in forming a layer with good moisture barrier properties.

It is therefore preferred that at least one layer of the multi-layer conformal coating is obtainable by plasma deposition of a precursor mixture comprising an organosilicon compound and O₂, N₂O and/or NO₂, and preferably also He, Ar and/or Kr. Preferably the precursor mixture consists, or consists essentially, of these components.

A layer containing nitrogen atoms will also typically have desirable moisture barrier properties. Such a layer can be obtained by using a nitrogen-containing organosilicon compound, typically a silazane or aminosilane precursor, such as the compounds of formula (IV) to (VI) defined above. Nitrogen atoms can also be introduced by including N₂, NO₂, N₂O or NH₃ as a reactive gas in the precursor mixture.

It is therefore also preferred that at least one layer of the multi-layer conformal coating is obtainable by plasma deposition of a precursor mixture comprising a nitrogen-containing organosilicon compound, N₂, NO₂, N₂O and/or NH₃. Preferably the precursor mixture consists, or consists essentially, of these components.

### Other Properties

The multi-layer conformal coatings are generally anti-corrosive and chemically stable, and thus resistant to immersion in, for example, acid or base or solvents such as acetone or isopropyl alcohol (IPA).

The thickness of the multi-layer conformal coating of the present invention will depend upon the number of layers that are deposited, and the thickness of each layer deposited.

Typically, the first/lowest layer and the final/uppermost layer have a thickness of from 0.05 μm to 5 μm. Typically, any layers present between the first/lowest layer and the final/uppermost layer have a thickness of from 0.1 μm to 5 μm.

The overall thickness of the multi-layer conformal coating is of course dependent on the number of layers, but is typically from 0.1 μm to 20 μm, preferably from 0.1 μm to 5 μm.

The thickness of each layer can be easily controlled by a skilled person. Plasma processes deposit a material at a uniform rate for a given set of conditions, and thus the thickness of a layer is proportional to the deposition time. Accordingly, once the rate of deposition has been determined, a layer with a specific thickness can be deposited by controlling the duration of deposition.

The thickness of the multi-layer conformal coating and each constituent layer may be substantially uniform or may vary from point to point, but is preferably substantially uniform.

Thickness may be measured using techniques known to those skilled in the art, such as a profilometry, reflectometry or spectroscopic ellipsometry.

Adhesion between layers of the multi-layer conformal coating can be improved, where necessary, by introducing a graded boundary between layers, as discussed above. Graded boundaries are particularly preferred for layers which contain fluorine, since these tend to exhibit poor adhesion. Thus, if a given layer contains fluorine, it preferably has a graded boundary with the adjacent layer(s).

Alternatively, where necessary, discrete layers within the multi-layer conformal coating can be chosen such that they adhere well to the adjacent layers within the multi-layer conformal coating.

### The Electrical Assembly

An electrical assembly used in the present invention typically comprises a substrate comprising an insulating material, a plurality of conductive tracks present on at least one surface of the substrate, and at least one electrical component connected to at least one conductive track. The electrical assembly is preferably a printed circuit board (PCB). The conformal coating preferably covers the plurality of conductive tracks, the at least one electrical component and the surface of the substrate on which the plurality of conductive tracks and the at least one electrical component are located. Alternatively, the coating may cover one or more electrical components, typically expensive electrical components in the PCB, whilst other parts of the electrical assembly are uncovered.

A conductive track typically comprises any suitable electrically conductive material. Preferably, a conductive track comprises gold, tungsten, copper, silver, aluminium, doped regions of semi-conductor substrates, conductive polymers and/or conductive inks. More preferably, a conductive track comprises gold, tungsten, copper, silver or aluminium.

Suitable shapes and configurations for the conductive tracks can be selected by a person skilled in the art for the particular assembly in question. Typically, a conductive track is attached to the surface of the substrate along its entire length. Alternatively, a conductive track may be attached to the substrate at two or more points. For example, a conductive track may be a wire attached to the substrate at two or more points, but not along its entire length.

A conductive track is typically formed on a substrate using any suitable method known to those skilled in the art. In a preferred method, conductive tracks are formed on a substrate using a “subtractive” technique. Typically in this method, a layer of metal (e.g., copper foil, aluminium foil, etc.) is bonded to a surface of the substrate and then the unwanted portions of the metal layer are removed, leaving the desired conductive tracks. The unwanted portions of the metal layer are typically removed from the substrate by chemical etching or photo-etching or milling. In an alternative preferred method, conductive tracks are formed on the substrate using an “additive” technique such as, for example, electroplating, deposition using a reverse mask, and/or any geometrically controlled deposition process. Alternatively, the substrate may be a silicon die or wafer, which typically has doped regions as the conductive tracks.

The substrate typically comprises any suitable insulating material that prevents the substrate from shorting the circuit of electrical assembly. The substrate preferably comprises an epoxy laminate material, a synthetic resin bonded paper, an epoxy resin bonded glass fabric (ERBGH), a composite epoxy material (CEM), PTFE (Teflon), or other polymer materials, phenolic cotton paper, silicon, glass, ceramic, paper, cardboard, natural and/or synthetic wood based materials, and/or other suitable textiles. The substrate optionally further comprises a flame retardant material, typically Flame Retardant 2 (FR-2) and/or Flame Retardant 4 (FR-4). The substrate may comprise a single layer of an insulating material or multiple layers of the same or different insulating materials. The substrate may be the board of a printed circuit board (PCB) made of any one of the materials listed above.

An electrical component may be any suitable circuit element of an electrical assembly. Preferably, an electrical component is a resistor, capacitor, transistor, diode, amplifier, relay, transformer, battery, fuse, integrated circuit, switch, LED, LED display, Piezo element, optoelectronic component, antenna or oscillator. Any suitable number and/or combination of electrical components may be connected to the electrical assembly.

The electrical component is preferably connected to an electrically conductive track via a bond. The bond is preferably a solder joint, a weld joint, a wire-bond joint, a conductive adhesive joint, a crimp connection, or a press-fit joint. Suitable soldering, welding, wire-bonding, conductive-adhesive and press-fit techniques are known to those skilled in the art, for forming the bond. More preferably the bond is a solder joint, a weld joint or a wire-bond joint, with a solder joint most preferred.

### DETAILED DESCRIPTION OF THE FIGURES

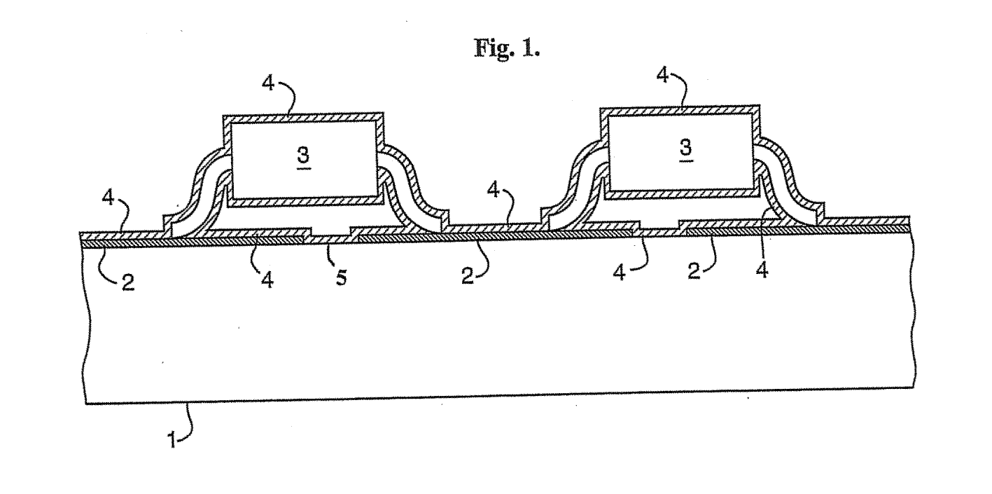

Aspects of the invention will now be described with reference to the embodiment shown in FIGS. 1 to 4, in which like reference numerals refer to the same or similar components.

FIG. 1 shows an example of an electrical assembly of the invention. The electrical assembly comprises a substrate 1 comprising an insulating material, a plurality of conductive tracks 2 present on least one surface of the substrate 1, and at least one electrical component 3 connected to at least one conductive track 2. The multi-layer conformal coating 4 covers the plurality of conductive tracks 2, the at least one electrical component 3 and the surface 5 of the substrate 1 on which the plurality of conductive tracks and the at least one electrical component are located.

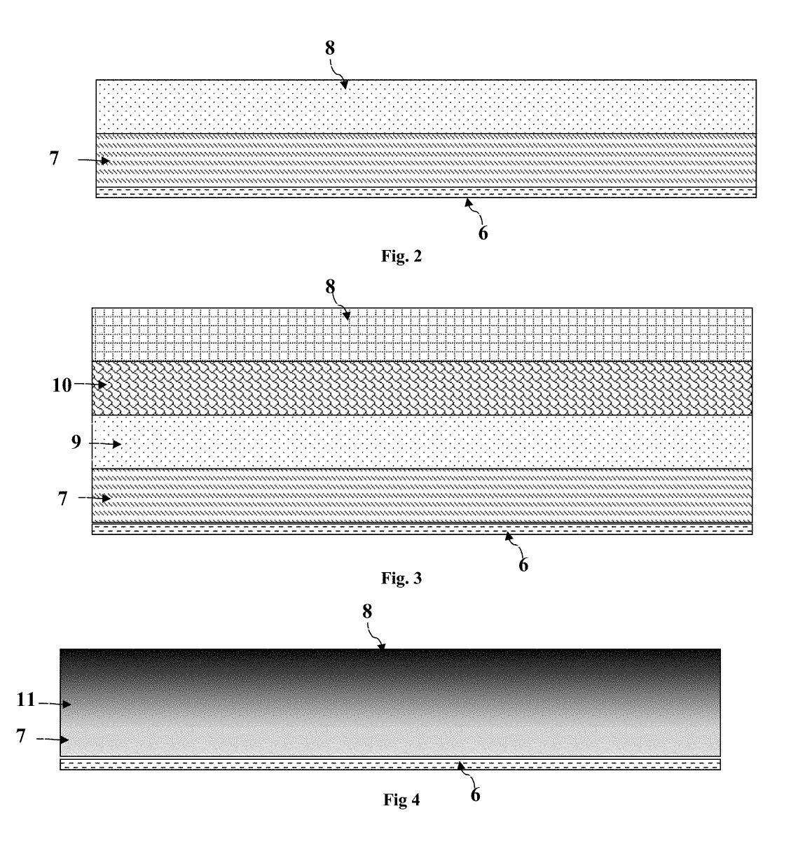

FIG. 2 shows a cross section through a preferred example of the multi-layer conformal coating 4 in FIG. 1. The multi-layer conformal coating comprises a first/lowest layer 7 which is in contact with the at least one surface 6 of the electrical assembly, and a final/uppermost layer 8. This multi-layer conformal coating has two layers, and the boundary between the layers is discrete.

FIG. 3 shows a cross section through another preferred example of the multi-layer conformal coating 4 in FIG. 1. The multi-layer conformal coating comprises a first/lowest layer 7 which is in contact with the at least one surface 6 of the electrical assembly, and a final/uppermost layer 8. Between layers 7 and 8 are two further layers 9 and 10. This multi-layer conformal coating has four layers, and the boundary between the layers is discrete.

FIG. 4 shows a cross section through another preferred example of the multi-layer conformal coating 4 in FIG. 1. The multi-layer conformal coating comprises a first/lowest layer 7 which is in contact with the at least one surface 6 of the electrical assembly, and a final/uppermost layer 8. This multi-layer conformal coating has two layers, and the boundary 11 between the layers is graded.

### EXAMPLES

Aspects of the invention will now be described with reference to the Examples below.

### Example 1

### Deposition of a Single SiOₓC_{y}H_{z} Layer

An electrical assembly was placed into a plasma-enhanced chemical vapour deposition (PECVD) deposition chamber, and the pressure was then brought to <10⁻³ mbar. He was injected at a flow rate resulting in a chamber pressure of 0.480 mbar, then it was increased (by means of a throttle valve) to 0.50 mbar. Plasma was ignited at RF power of 45 W for 3-5 seconds. Next, HMDSO was injected into the chamber at a flow rate of 6 sccm and RF power density was at 0.225, 0.382, 0.573 or 0.637 Wcm⁻² for 20 minutes. Pressure was kept (through a throttle valve) at 0.5 mbar during the deposition process.

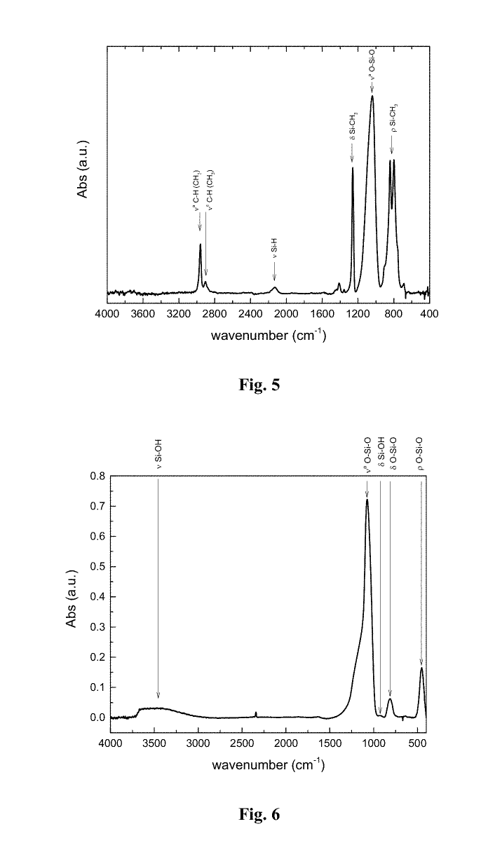

Polymeric organosilicon SiOₓC_{y}H_{z} layers were obtained on the electrical assembly. The FT-IR transmission spectra for the layer obtained using an RF power density of 0.637 Wcm⁻² is shown in FIG. 5.

The SiOₓC_{y}H_{z} layers showed hydrophobic character with a WCA (water contact angle) of ˜100°.

The coated electrical assemblies (combs and pads) were tested for electrical resistance while immersed into deionized (DI) water by applying 5 V into the circuit. The results are set out in Table 1 below.

TABLE 1

| RF | Thickness | Electrical feature | | | | | |
|---|---|---|---|---|---|---|---|
| power | of coating | Comb A | Comb A′ | Comb B′ | Comb B | Pads | Pads′ |
| (W) | (nm) | R (Ω) at 1′ | R (Ω) at 1′ | R (Ω) at 1′ | R (Ω) at 1′ | R (Ω) at 1′ | R (Ω) at 1′ |
| 20 | 550 | 5.56E+08 | 3.00E+08 | 1.72E+08 | 7.63E+07 | 6.98E+10 | 1.25E+10 |
| 30 | 680 | 1.61E+07 | 4.56E+07 | 1.93E+07 | 4.05E+07 | 9.00E+09 | 2.93E+12 |
| 40 | 1170 | 1.61E+07 | 4.56E+07 | 1.93E+07 | 4.05E+07 | 9.00E+09 | 2.93E+12 |
| 50 | 1260 | 1.56E+08 | 1.02E+08 | 1.16E+08 | 6.99E+07 | 3.53E+10 | 3.37E+12 |

### Example 2

### Deposition of Single SiOₓH_{z} Layer

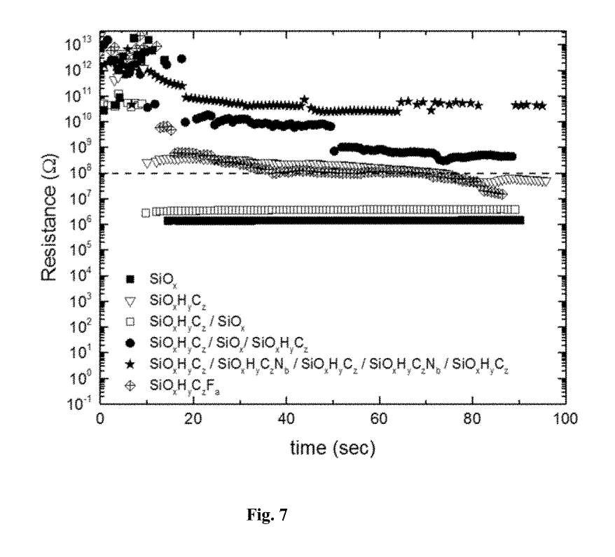

An electrical assembly was placed into a PECVD deposition chamber, and the pressure was then brought to <10⁻³ mbar. Against this base pressure, O₂ was inject up to 0.250 mbar of chamber pressure. After that, He was injected in order to reach a chamber pressure of 0.280 mbar. Finally, HMDSO was injected at a flow rate of 2.5 sccm and pressure was increased (by means of throttle valve) to 0.300 mbar. Plasma was then ignited with a power density of 0.892 Wcm⁻² and the process was continued until the desired thickness of approximate 750 nm was achieved. A SiOₓH_{z} layer was obtained with FT-IR transmission spectrum as shown in FIG. 6. The SiOₓH_{z} layer showed hydrophilic character with a WCA ˜50°.

### Example 3

### Deposition of SiOₓC_{y}H_{z}/SiOₓH_{z} Multilayer

The experimental conditions leading to the PECVD deposition of the SiOₓC_{y}H_{z}/SiOₓH_{z} multilayers on electrical assemblies were basically the same as described in Examples 1 and 2. Briefly, SiOₓC_{y}H_{z} was deposited with the same procedure explained in Example 1 (RF power density used for this experiment was 0.637 Wcm⁻²), then chamber was brought to vacuum (<10⁻³ mbar) and the deposition of SiOₓH_{z}, on top of the SiOₓC_{y}H_{z} layer, was performed according to the procedure explained in Example 2. Then, a second SiOₓC_{y}H_{z} layer was deposited on top of the SiOₓH_{z} layer. The thickness of the second SiOₓC_{y}H_{z} layer was half that of the first SiOₓC_{y}H_{z} layer. This was achieved by halving the deposition time. These steps resulted in multilayer coating with the structure: SiOₓC_{y}H_{z}/ SiOₓH_{z}/SiOₓC_{y}H_{z}.

The process was then repeated on some electrical assemblies in order to add a second pair of SiOₓC_{y}H_{z}/SiOₓH_{z} layer, thereby giving the structure: SiOₓC_{y}H_{z}/SiOₓH_{z}/SiOₓC_{y}H_{z}/SiOₓH_{z}/SiOₓC_{y}H_{z}.

Electrical assemblies coated with these two multilayers were tested for electrical resistance while immersed into DI water by applying 5 V into the circuit. The results are listed in Table 2 below.

TABLE 2

| | Electrical feature | | | | | |
|---|---|---|---|---|---|---|
| Multilayer | Comb A | Comb A′ | Comb B′ | Comb B | Pads | Pads′ |
| structure | R (Ω) at 1′ | R (Ω) at 1′ | R (Ω) at 1′ | R (Ω) at 1′ | R (Ω) at 1′ | R (Ω) at 1′ |
| SiOₓC_{y}H_{z}/SiOₓH_{z}/SiOₓC_{y}H_{z} | 6.48E+08 | 2.03E+08 | 2.39E+10 | 1.71E+09 | 8.66E+11 | 1.55E+12 |
| SiOₓC_{y}H_{z}/SiOₓH_{z}/SiOₓC_{y}H_{z}/SiOₓH_{z}/SiOₓC_{y}H_{z} | 2.57E+10 | 6.64E+10 | 5.24E+09 | 8.15E+09 | 1.78E+12 | 1.43E+12 |

The performances of the multilayers were tested also the following way. A 5V potential was applied across the coated electrical assemblies, which were immersed in a sweat solution. A failure was recorded when the current leakage across the coating reached 50 μA. The results are set out below in Table 3

TABLE 3

| | Electrical feature | | | |
|---|---|---|---|---|
| | Comb A | Comb B | Pads | |
| | Time to | Time to | Time | Pads′ |
| Multilayer | failure | failure | to failure | Time to failure |
| structure | (min) | (min) | (min) | (min) |
| SiOₓC_{y}H_{z}/SiOₓH_{z}/ | 6.9 | 19.9 | 6.9 | 6.95 |
| SiOₓC_{y}H_{z} | | | | |
| SiOₓC_{y}H_{z}/SiOₓH_{z}/ | 65.7 | 32.9 | 291.4 | 327.1 |
| SiOₓC_{y}H_{z}/SiOₓH_{z}/ | | | | |
| SiOₓC_{y}H_{z} | | | | |

### Example 4

### Assessment of Properties of Conformal Coatings

Conformal coatings were deposited onto combs under the conditions set out below.

### 1. Deposition Conditions for SiOₓ Coating

Against a base pressure of 10⁻³ mbar, O₂ was inject up to 0.250 mbar of chamber pressure. After that, He was injected in order to reach a chamber pressure of 0.280 mbar. HMDSO was added at flow rate of 2.5 sccm. Pressure was set to 0.280 mbar. Plasma was ignited at a power density of 0.892 Wcm⁻².

2. Deposition Conditions for SiOₓC_{y}H_{z} Coating

Against a base pressure of 10⁻³ mbar, He was injected at a flow rate resulting in a chamber pressure of 0.480 mbar, then the pressure was increased (by means of a throttle valve) to 0.50 mbar. Plasma was ignited at RF power density of 0.573 Wcm⁻² for 3-5 seconds. Next, HMDSO was injected into the chamber at a flow rate of 6 sccm together and RF power density of 0.637 Wcm⁻².

3. Deposition Conditions for SiOₓC_{y}H_{z}/SiOₓ Coating

An SiOₓC_{y}H_{z} layer was deposited as described in paragraph 2 above. Then the deposition chamber was evacuated and the SiOₓ layer was deposited on top of the SiOₓC_{y}H_{z} layer as described in paragraph 1 above.

4. Deposition Conditions for SiOₓC_{y}H_{z}/SiOₓ/SiOₓC_{y}H_{z} Coating

An SiOₓC_{y}H_{z} layer was deposited as described in paragraph 2 above. Then the deposition chamber was evacuated and the SiOₓ coating was deposited on top of the SiOₓC_{y}H_{z} layer with the same conditions as described in paragraph 1 above (except for the fact that HMDSO and He mixture was injected and RF plasma was ignited directly at a power density of 0.637 Wcm⁻²). Finally, the deposition chamber was evacuated and a second SiOₓC_{y}H_{z} layer was deposited on top of the SiOₓ layer with the conditions described in paragraph 2 above.

5. Deposition of SiOₓC_{y}H_{z}/ SiOₓH_{y}C_{z}N_{b}/ SiOₓC_{y}H_{z}/SiOₓH_{y}C_{z}N_{b}/SiOₓC_{y}H_{z} Coating

The SiOₓC_{y}H_{z} layers were deposited by mixing 17.5 sccm of HMDSO with 20 sccm of Ar at a RF power density of 0.057 Wcm⁻², while the SiOₓH_{y}C_{z}N_{b} layers were deposited by mixing 17.5 sccm of HMDSO with 15 sccm of N₂O at a RF power density of 0.057 Wcm⁻².

6. Deposition Conditions for SiOₓH_{y}C_{z}Fₐ Layer

A SiOₓC_{y}H_{z}Fₐ layer was deposited by mixing 17.5 sccm of HMDSO with 20 sccm of HPF at a RF power density of 0.057 Wcm⁻².

The coated combs were then tested as follows. Water was placed on the coated combs and power was then applied across the poles of the coated combs. Electrical resistance was measured over time, with a high resistance indicating that the coating was intact and that no current was following. As soon as the coating started leaking water, current started to pass between the poles of the component and resistance decreased. Coating failure was deemed to have occurred when resistance fell below 10⁸ Ω.

The results of this test are depicted in FIG. 7. The SiOₓC_{y}H_{z}/SiOₓ/SiOₓC_{y}H_{z} coating performed well (see the black circles), with a high resistance throughout the duration of the test. The SiOₓC_{y}H_{z}/SiOₓH_{y}C_{z}N_{b}/SiOₓC_{y}H_{z}/SiOₓH_{y}C_{z}N_{b}/SiOₓC_{y}H_{z} also performed well (see the black stars), with an even higher resistance throughout the duration of the test. The three single layer coatings (SiOₓ [black squares], SiOₓC_{y}H_{z} [unshaded triangles] and SiOₓH_{y}C_{z}Fₐ [diamonds]) failed, with resistance either starting below 10⁸ Ω (for the SiOₓ layer) or decreasing to under 10⁸ Ω during the duration of the test (for the SiOₓC_{y}H_{z} and SiOₓH_{y}C_{z}Fₐ layers).

The SiOₓC_{y}H_{z}/ SiOₓ two layer coating (unshaded squares) also failed in this test, performing less well than the SiOₓC_{y}H_{z} single layer coating. It was notable that addition of a further SiOₓC_{y}H_{z} layer on top of the SiOₓC_{y}H_{z}/SiOₓ coating greatly improved its performance as discussed above. It is believed that whilst a SiOₓ layer as the top layer of the coating may result in reduced performance under some conditions for coatings with low numbers of layers (such as SiOₓC_{y}H_{z}/ SiOₓ), such a reduction in performance is unlikely to be observed when there are higher number of layers in the coating.

1.-20. (canceled)

21. An electrical assembly which has a multi-layer conformal coating on at least one surface of the electrical assembly, wherein the multi-layer conformal coating is obtained by:
contacting the electrical assembly with a first precursor mixture comprising at least one organosilicon compound, under plasma deposition conditions suitable to form a first layer of the multi-layer conformal coating in contact with the electrical assembly, wherein the first layer is organic and hydrophobic, and wherein the first precursor mixture contains no, or substantially no, O₂, N₂O or NO₂; and
contacting the electrical assembly with a second precursor mixture comprising at least one organosilicon compound, under plasma deposition conditions suitable to form a second layer of the multi-layer conformal coating, wherein the second layer is organic and hydrophobic, and wherein the second precursor mixture contains no, or substantially no, O₂, N₂O or NO₂.

22. The electrical assembly according to claim 21, wherein the multi-layer conformal coating has two to ten layers.

23. The electrical assembly according to claim 21, wherein the plasma deposition is plasma enhanced chemical vapour deposition (PECVD).

24. The electrical assembly according to claim 21, wherein the plasma deposition occurs at a pressure of 0.001 to 10 mbar.

25. The electrical assembly according to claim 21, wherein the first precursor mixture contains no, or substantially no, fluorine-containing organosilicon compound, SiF₄ or HFP.

26. The electrical assembly according to claim 21, wherein the second precursor mixture comprises at least one of one or more halogen-containing organosilicon compounds, SiF₄ and HFP.

27. The electrical assembly according to claim 21, wherein the second precursor mixture comprises at least one of He, Ar and Kr.

28. The electrical assembly according to claim 21, wherein each organosilicon compound is independently selected from hexamethyldisiloxane (HMDSO), tetramethyldisiloxane (TMDSO), 1,3-divinyltetramethyldisiloxane (DVTMDSO), hexavinyldisiloxane (HVDSO allyltrimethylsilane, allyltrimethoxysilane (ATMOS), tetraethylorthosilicate (TEOS), trimethylsilane (TMS), triisopropylsilane (TiPS), trivinyl-trimethyl-cyclotrisiloxane (V₃D₃), tetravinyl-tetramethyl-cyclotetrasiloxane (V₄D₄), tetramethylcyclotetrasiloxane (TMCS), octamethylcyclotetrasiloxane (OMCTS), hexamethyldisilazane (HIVIDSN), 2,4,6-trimethyl-2,4,6-trivinylcyclotrisilazane, dimethylamino-trimethylsilane (DMATMS), bis(dimethylamino)dimethylsilane, (BDMADMS), tris(dimethylamino)methylsilane (TDMAMS), trimethyl(trifluoromethyl)silane or 1H,1H,2H,2H-perfluorooctyltriethoxysilane and 3-(Diethylamino)propyl-trimethoxysilane.

29. The electrical assembly according to claim 21, wherein the electrical assembly comprises a substrate comprising an insulating material, a plurality of conductive tracks present on least one surface of the substrate, and at least one electrical component connected to at least one conductive track.

30. The electrical assembly according to claim 29, wherein the multi-layer conformal coating covers the plurality of conductive tracks, the at least one electrical component and the surface of the substrate on which the plurality of conductive tracks and the at least one electrical component are located.

31. The electrical assembly according to claim 21, which is a printed circuit board.

32. The electrical assembly according to claim 21, wherein the multi-layer conformal coating further comprises 1 to 8 additional layers each obtained by contacting the first layer, or one of the additional layers, with a subsequent precursor mixture comprising at least one organosilicon compound, under plasma deposition conditions suitable to form the additional layer of the multi-layer conformal coating.

33. The electrical assembly according to claim 32, wherein each additional layer is located between the first and second layers.

34. The electrical assembly according to claim 32, wherein the multi-layer conformal coating has four to eight layers.

35. The electrical assembly according to claim 32, wherein at least one of the additional layers of the multi-layer conformal coating is a moisture barrier layer obtained by contacting the first layer, or one of the additional layers, with a third precursor mixture comprising an organosilicon compound and at least one of O₂, N₂O and NO₂, under plasma deposition conditions suitable to form the moisture barrier layer.

36. The electrical assembly according to claim 35, wherein the third precursor mixture further comprises at least one of He, Ar and Kr.

37. The electrical assembly according to claim 35, wherein the moisture barrier layer is located between the first layer and the second layer of the multi-layer coating.

38. The electrical assembly according to claim 32, wherein at least one of the additional layers of the multi-layer conformal coating is a moisture barrier layer obtained by contacting the first layer, or one of the subsequent layers, with a third precursor mixture comprising an organosilicon compound and at least one of a nitrogen-containing organosilicon compound, N₂, NO₂, N₂O and NH₃, under plasma deposition conditions suitable to form the moisture barrier layer.

39. An electrical component which has a multi-layer conformal coating as defined in claim 21 on at least one surface of the electrical component.

40. The electrical component according to claim 39, which is a resistor, capacitor, transistor, diode, amplifier, relay, transformer, battery, fuse, integrated circuit, switch, LED, LED display, Piezo element, optoelectronic component, antenna or oscillator.
